(19) United States
(12) Patent Application Publication
(10) Pub. No.: US 2026/0344193 A1
(43) Pub. Date: Oct. 29, 2026

(54) DISPLAY DEVICE AND ELECTRONIC DEVICE INCLUDING THE SAME

(71) Applicant: Samsung Display Co., Ltd., Yongin-si (KR)

(72) Inventors: DALRAE JIN, Yongin-si (KR); DONG-UK KIM, Yongin-si (KR); HYUN-CHUL PARK, Yongin-si (KR); HOJUN LEE, Yongin-si (KR); LOK-GAM JUNG, Yongin-si (KR)

(21) Appl. No.: 19/651,603

(22) Filed: Apr. 17, 2026

(30) Foreign Application Priority Data
Apr. 25, 2025 (KR) 10-2025-0054634

(51) Int. Cl. H10K 59/122

(52) U.S. Cl. CPC H10K 59/122

(57) ABSTRACT

A display device including a semiconductor circuit substrate including a pixel circuit, a reflective conductive pattern on the semiconductor circuit substrate, an emission element including a first electrode, an emission unit, and a second electrode, a pixel definition layer on the semiconductor circuit substrate having an emission opening that exposes the first electrode, and a peripheral emission unit on the pixel definition layer. The pixel definition layer includes a silicon nitride layer directly on the first electrode and a silicon oxide layer directly on the silicon nitride layer. The silicon oxide layer defines a tip structure that protrudes more inward from the emission opening than the silicon nitride layer. The peripheral emission unit is directly on the silicon oxide layer and electrically separated through the tip structure from the emission unit.

### CROSS-REFERENCE TO RELATED APPLICATION

The present application claims priority to and the benefit of Korean Patent Application No. 10-2025-0054634, filed on Apr. 25, 2025, in the Korean Intellectual Property Office, the entire disclosure of which is incorporated herein by reference.

### BACKGROUND

### 1. Field

Embodiments of the present disclosure described herein are related to a display device and an electronic device including the same, and, for example, to a display device including a semiconductor circuit substrate and an electronic device including the same.

### 2. Description of Related Art

A display device for displaying images is included in an electronic device for providing images to users, such as smart phones, laptop computers, navigation systems, smart televisions, and/or the like. The display device may include high-resolution image display devices, such as virtual reality (VR) devices, augmented reality (AR) devices, and smart watches. A high-resolution display device may include a light emitting diode on silicon (LEDoS) and/or an organic light emitting diode on silicon (OLEDoS) each including a silicon substrate and an emission element on the silicon substrate.

The high-resolution display device may have a narrower gap between pixels due to the decreasing size of each individual pixel. Consequently, a lateral leakage current between neighboring pixels may occur to cause a reduction in image quality.

The information disclosed in this Background section is intended to enhance understanding of the background of the disclosure and therefore it may contain information that does not constitute prior art.

### SUMMARY

Aspects according to one or more embodiments of the present disclosure are directed towards a display device with enhanced (e.g., improved) image quality and increased reliability.

Aspects according to one or more embodiments of the present disclosure are directed toward an electronic device including the display device.

Additional aspects of embodiments will be set forth in part in the description which follows and, in part, will be apparent from the description, or may be learned by practice of the presented embodiments of the disclosure.

According to one or more embodiments of the present disclosure, a display device may include: a semiconductor circuit substrate including a pixel circuit; a reflective conductive pattern on the semiconductor circuit substrate; an emission element including a first electrode in contact with the reflective conductive pattern, an emission unit on the first electrode, and a second electrode on the emission unit, the emission element being on the semiconductor circuit substrate; a pixel definition layer on the semiconductor circuit substrate and having an emission opening that exposes the first electrode; and a peripheral emission unit on the pixel definition layer. The pixel definition layer may include: a silicon nitride layer directly on the first electrode; and a silicon oxide layer directly on the silicon nitride layer. The silicon oxide layer may define a tip structure that protrudes more inward from the emission opening than the silicon nitride layer. The peripheral emission unit may be directly on the silicon oxide layer and electrically separated through the tip structure from the emission unit.

In one or more embodiments, the display device may further include an interlayer dielectric layer between the reflective conductive pattern and the first electrode. The first electrode may be in contact with a lateral surface of the reflective conductive pattern.

In one or more embodiments, the silicon nitride layer may be around (e.g., surround) the first electrode. The first electrode may be in contact with a lateral surface of the reflective conductive pattern. The pixel definition layer may further include a lower silicon oxide layer between the silicon oxide layer and the semiconductor circuit substrate. The lower silicon oxide layer may be around (e.g., surround) the silicon nitride layer.

In one or more embodiments, a thickness of the silicon nitride layer may be in a range of about 50 Å to about 100 Å.

In one or more embodiments, the tip structure may have a bottom surface and an inclined surface. The inclined surface of the tip structure may form an acute angle relative to the bottom surface of the tip structure.

In one or more embodiments, the acute angle may be in a range of about 30° to about 60°.

In one or more embodiments, each of the emission unit and the peripheral emission unit may include: a hole injection layer; a hole transport layer on the hole injection layer; an emission layer on the hole transport layer; an electron transport layer on the emission layer; and an electron injection layer on the electron transport layer. The hole injection layer of the emission unit and the hole injection layer of the peripheral emission unit may be spaced and/or apart (e.g., spaced apart or separated) from each other through the tip structure.

In one or more embodiments, the second electrode may further extend onto the peripheral emission unit.

In one or more embodiments, the pixel definition layer may further include: a lower silicon nitride layer in contact with a lateral surface of the reflective conductive pattern; and a lower silicon oxide layer between the silicon nitride layer and the semiconductor circuit substrate. The lower silicon oxide layer may be around (e.g., surround) the lower silicon nitride layer.

In one or more embodiments, the reflective conductive pattern may include: a first reflective layer; and a second reflective layer on the first reflective layer and in contact with the first electrode.

In one or more embodiments, the first electrode may include: a 1-1^{st} electrode directly on the second reflective layer and including transparent conductive oxide; and a 1-2^{nd} electrode on the 1-1^{st} electrode and including titanium nitride.

In one or more embodiments, a thickness of the 1-2^{nd} electrode may be in a range of about 10 Å to about 20 Å.

According to one or more embodiments of the present disclosure, a display device may include: a semiconductor circuit substrate including a pixel circuit; a reflective conductive pattern (e.g., a reflective electrically conductive pattern) on the semiconductor circuit substrate; an emission element including a first electrode in contact with the reflective conductive pattern, an emission unit on the first electrode, and a second electrode on the emission unit, the emission element being on the semiconductor circuit substrate; a pixel definition layer on the semiconductor circuit substrate and having an emission opening that exposes the first electrode; and a peripheral emission unit on the pixel definition layer. The pixel definition layer may include: a 1-1^{st} silicon nitride layer directly on the first electrode; a 1-2^{nd} silicon nitride layer on the 1-1^{st} silicon nitride layer; and a silicon oxide layer directly on the 1-2^{nd} silicon nitride layer. The 1-2^{nd} silicon nitride layer may include a protrusion that protrudes more inward from the emission opening than the 1-1^{st} silicon nitride layer. The silicon oxide layer may define a tip structure that protrudes more inward from the emission opening than the protrusion of the 1-1^{st} silicon nitride layer. The peripheral emission unit may be directly on the silicon oxide layer and electrically separated through the tip structure from the emission unit.

In one or more embodiments, the pixel definition layer may further include a lower silicon oxide layer between the 1-1^{st} silicon nitride layer and the 1-2^{nd} silicon nitride layer.

In one or more embodiments, the tip structure may have a bottom surface and an inclined surface. The inclined surface of the tip structure may form an acute angle relative to the bottom surface of the tip structure. An angle between an inner lateral surface of the protrusion of the 1-1^{st} silicon nitride layer and a top surface of the first electrode may be greater than the acute angle.

In one or more embodiments, the protrusion of the 1-1^{st} silicon nitride layer may provide a step difference. A portion of the silicon oxide layer may be on the step difference.

In one or more embodiments, each of the emission unit and the peripheral emission unit may include: a hole injection layer; a hole transport layer on the hole injection layer; an emission layer on the hole transport layer; an electron transport layer on the emission layer; and an electron injection layer on the electron transport layer. The hole injection layer of the emission unit and the hole injection layer of the peripheral emission unit may be spaced and/or apart (e.g., spaced apart or separated) from each other through the tip structure.

In one or more embodiments, the display device may further include an interlayer dielectric layer between the reflective conductive pattern and the first electrode. The first electrode may be in contact with a lateral surface of the reflective conductive pattern.

According to one or more embodiments of the present disclosure, an electronic device may include: a display device; a power module that supplies the display device with power; and a processor connected to the display device.

The display device may include: a semiconductor circuit substrate including a pixel circuit; a reflective conductive pattern (e.g., a reflective electrically conductive pattern) on the semiconductor circuit substrate; an emission element including a first electrode in contact with the reflective conductive pattern, an emission unit on the first electrode, and a second electrode on the emission unit, the emission element being on the semiconductor circuit substrate; a pixel definition layer on the semiconductor circuit substrate and having an emission opening that exposes the first electrode; and a peripheral emission unit on the pixel definition layer. The pixel definition layer may include: a silicon nitride layer directly on the first electrode; and a silicon oxide layer directly on the silicon nitride layer. The silicon oxide layer may define a tip structure that protrudes more inward from the emission opening than the silicon nitride layer. The peripheral emission unit may be directly on the silicon oxide layer and electrically separated through the tip structure from the emission unit.

In one or more embodiments, a thickness of the silicon nitride layer may be in a range of about 50 Å to about 100 Å.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 illustrates a block diagram showing an electronic device according to one or more embodiments of the present disclosure.

FIG. 2 illustrates simplified diagrams showing electronic devices according to one or more suitable embodiments.

FIG. 3 illustrates a perspective view showing a display device according to one or more embodiments of the present disclosure.

FIG. 4 illustrates a simplified cross-sectional view showing a display device according to one or more embodiments of the present disclosure.

FIG. 5A illustrates a cross-sectional view showing a display panel according to one or more embodiments of the present disclosure.

FIG. 5B illustrates an enlarged cross-sectional view showing a display panel according to one or more embodiments of the present disclosure.

FIG. 6 illustrates a simplified enlarged cross-sectional view showing an emission element according to one or more embodiments of the present disclosure.

FIGS. 7A-7C illustrate cross-sectional views partially showing a method of fabricating a display panel according to one or more embodiments of the present disclosure.

FIG. 8A illustrates a cross-sectional view showing a display panel according to one or more embodiments of the present disclosure.

FIGS. 8B and 8C illustrate enlarged cross-sectional views showing a display panel according to one or embodiments of the present disclosure.

FIG. 9A illustrates a cross-sectional view showing one or more embodiments of the present disclosure.

FIG. 9B illustrates an enlarged cross-sectional view showing a display panel according to one or more embodiments of the present disclosure.

FIGS. 10A-10E illustrate cross-sectional views partially showing a method of fabricating a display panel according to one or more embodiments of the present disclosure.

### DETAILED DESCRIPTION

The subject matter of the present disclosure may be implemented to have various suitable modifications and have various suitable forms, and example embodiments are illustrated in the drawings and described in more detail in the text. It is to be understood, however, that the present disclosure is not intended to be limited to the particular forms disclosed, but on the contrary, is intended to cover all modifications, equivalents, and alternatives falling within the spirit and scope of the present disclosure.

In this specification, when a certain component (or region, layer, portion, and/or the like) is referred to as being “on”, “connected to”, or “coupled to” another component, the certain component may be directly arranged/connected/coupled to another component or at least one intervening component may be arranged therebetween.

Like numerals indicate like components. Moreover, in the drawings, thicknesses, ratios, dimensions of components, and/or the like may be exaggerated for effectively explaining the technical contents. The term “and/or” includes one or more combination defined by related components.

It will be understood that, although the terms “first,” “second,” etc. may be used herein to describe one or more suitable components, these components should not be limited by these terms. The terms are used only for the purpose of distinguish an element, a component, a region, a layer, or a part from another element, another component, another region, another layer, or another part. For example, without departing from the scope of the present disclosure, a first element, a first component, a first region, a first layer, or a first part could be termed a second element, a second component, a second region, a second layer, or a second part, and similarly, a second element, a second component, a second region, a second layer, or a second part could be also termed a first element, a first component, a first region, a first layer, or a first part. Unless the context clearly indicates otherwise, the singular forms are intended to include the plural forms as well.

In addition, the terms “beneath”, “lower”, “above”, “upper”, and the like may be used herein to describe one component’s relationship to other component illustrated in the drawings. The relative terms are intended to encompass different orientations in addition to the orientation depicted in the drawings.

The singular forms "a," "an," and "the" as used herein are intended to include the plural forms as well unless the context clearly indicates otherwise.

In the present disclosure, it should be further understood that the terms “comprise”, “include”, “have”, and the like are used to specify the presence of stated features, integers, steps, operations, components, elements, or combinations thereof, but do not preclude the presence or addition of one or more other features, integers, steps, operations, components, elements, or combinations thereof.

Unless otherwise defined, all terms used herein, including technical and scientific terms, have the same meaning generally understood by one of ordinary skilled in the art. Also, terms as defined in dictionaries generally used should be understood as having meaning identical or meaning contextually defined in the art and should not be understood in ideally or excessively formal meanings unless definitely defined herein.

The following describes one or more embodiments of the present disclosure in conjunction with the accompanying drawings.

A display device according to one or more embodiments may be applied to one or more suitable electronic devices. An electronic device according to one or more embodiments may include a display device, and may further include another functional module or apparatus besides the display device.

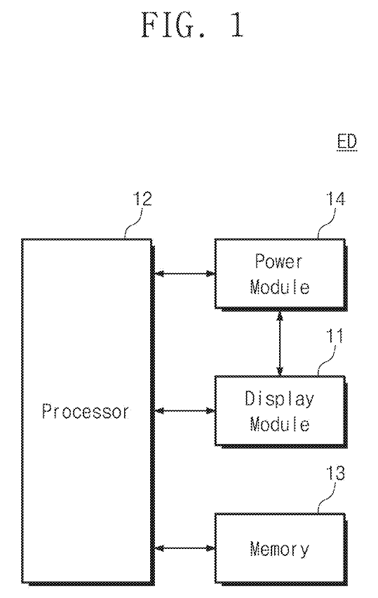

FIG. 1 illustrates a block diagram showing an electronic device ED according to one or more embodiments of the present disclosure.

Referring to FIG. 1, the electronic device ED according to one or more embodiments may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), or a controller.

The memory 13 may store data information required for the operation of the processor 12 or the display module 11. If (e.g., when) the processor 12 executes an application stored in the memory 13, the display module 11 may receive one or more of image data signals and input control signals, and may process the received one or more signals to output image information through a display screen.

The power module 14 may include a power supply module, such as a power adaptor or a battery device, and may also include a power conversion module configured or provided to convert power supplied by the power supply module to generate power required or desired for the operation of the electronic device ED.

At least one chosen from the components in the electronic device ED may be included in a display device according to one or more embodiments. In addition, one or more of the individual modules functionally included in one module may be included in a display device, and the others thereof may be provided separately from a display device. For example, the display module 11 may be included in a display device, and the processor 12, the memory 13, and the power module 14 may be provided in the form of other apparatuses within the electronic device ED rather than the display device.

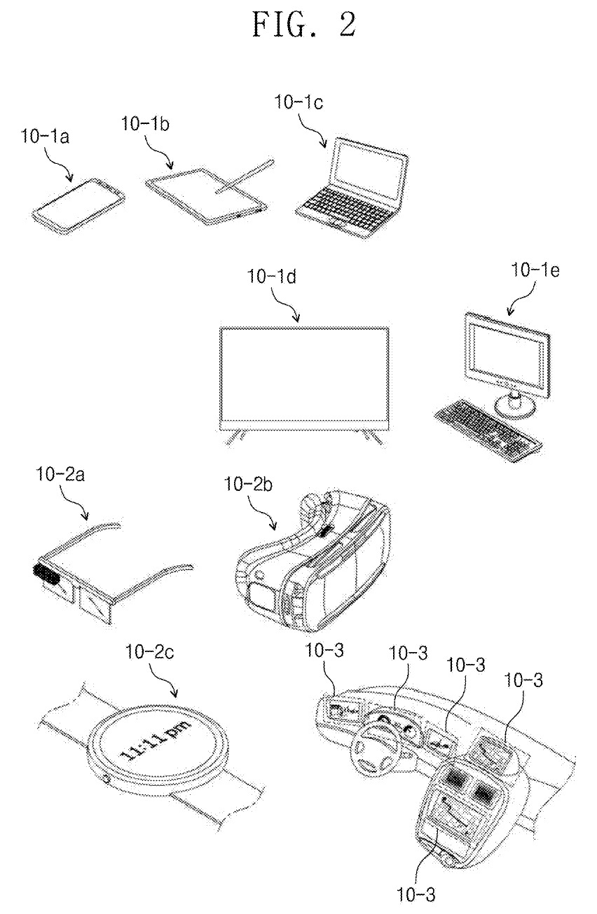

FIG. 2 illustrates simplified diagrams showing the electronic device ED according to one or more embodiments.

Referring to FIG. 2, various suitable electronic devices to each of which a display device according to one or more embodiments is applied may include an image display electronic device, such as a smart phone 10-1a, a tablet personal computer 10-1b, a laptop computer 10-1c, a television set 10-1d, and a desk monitor 10-1e, a wearable electronic device including a display module such as smart glasses 10-2a, a head-mounted display 10-2b, and a smart watch 10-2c, and a vehicle electronic device 10-3 including a display module such as an instrument cluster, a center fascia, a center information display (CID) arranged on a vehicle dashboard, and a room mirror display.

The smart phone 10-1a depicted in FIG. 2 may include, besides the display module, a communication module and an input module, such as a touch sensor. The smart phone 10-1a may process information received via its communication module or other input modules, and may display the received information through the display module of the display device. Like the smart phone 10-1a, each of the tablet personal computer 10-1b, the laptop computer 10-1c, the television set 10-1d, and the desk monitor 10-1e may include a display module and an input module, and optionally may further include a communication module.

The smart glasses 10-2a and the head-mounted display 10-2b depicted in FIG. 2 may include a display module that outputs a display image and a reflector that reflects the output display screen to the user’s eye, and through this, may provide the user with virtual reality or augmented reality screens. The smart watch 10-2c may include a bio-sensor as an input sensor, and may provide bio-information recognized through the bio-sensor to the user via the display module.

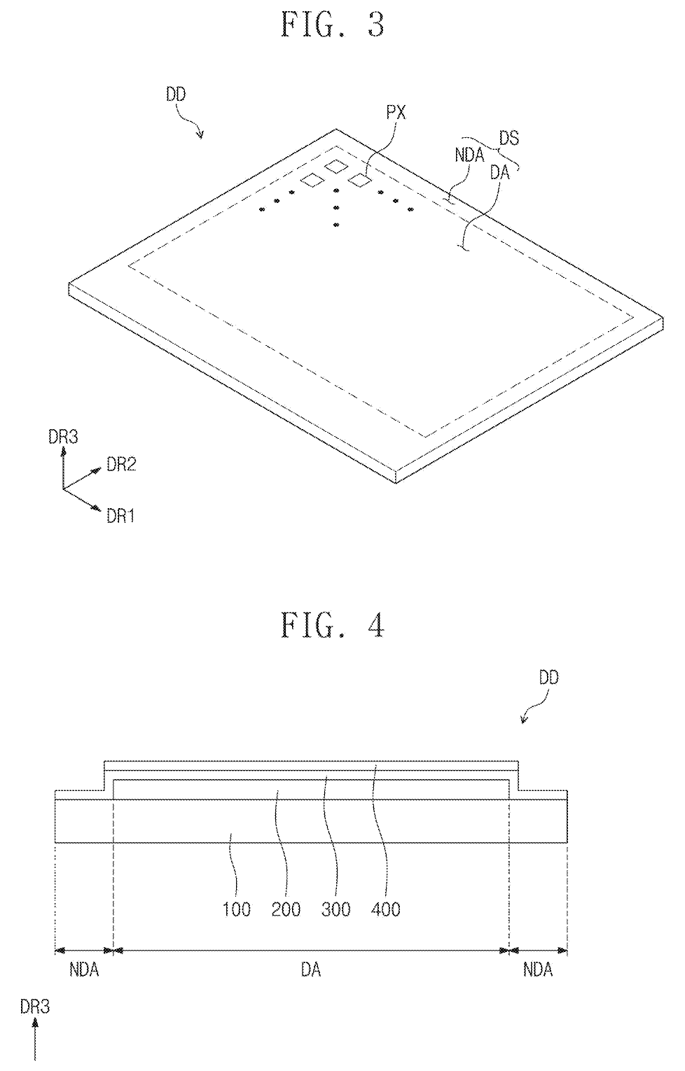

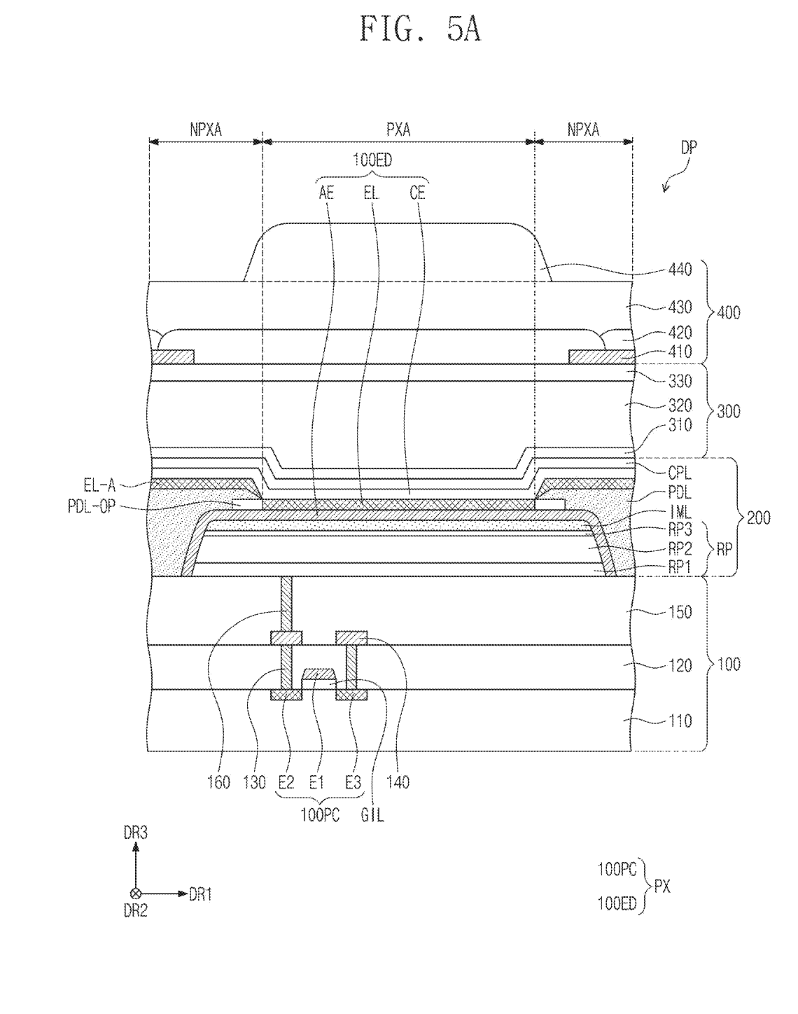

FIG. 3 illustrates a perspective view showing a display device DD according to one or more embodiments of the present disclosure. FIG. 4 illustrates a simplified cross-sectional view showing the display device DD according to one or more embodiments of the present disclosure.

Referring to FIG. 3, the display device DD according to one or more embodiments of the present disclosure may have a rectangular shape with long sides that extend in a first direction DR1 and short sides that extend in a second direction DR2 cross to the first direction DR1. The present disclosure, however, is not limited thereto, and the display device DD may have a circular shape, a polygonal shape, or any other suitable shapes. In the following description, a third direction DR3 may be defined as a direction that substantially vertically intersects a plane defined by the first direction DR1 and the second direction DR2. In this description, the phrase “when viewed in plan” may define the meaning of “when viewed in the third direction DR3.”

A top surface of the display device DD may be defined as a display surface DS, and may have a plane defined by the first direction DR1 and the second direction DR2. The display surface DS may provide users with images generated from the display device DD.

The display surface DS may include a display area DA and a non-display area NDA around (e.g., surrounding) the display area DA. The display area DA may display images, and the non-display area NDA may not display images. Although the non-display area NDA may be around (e.g., surround) the display area DA, the present disclosure is not limited thereto and the non-display area NDA may not be on one side of the display area DA.

A plurality of pixels PX may be arranged on the display area DA. The pixels PX may be arranged in a matrix form. Each of the pixels PX may include a pixel circuit and an emission element. The pixels PX may all generate the same-colored light. In one or more embodiments of the present disclosure, the pixels PX may include a plurality of groups that generate light having different colors from each other.

Referring to FIG. 4, the display device DD may include a semiconductor circuit substrate 100, an emission element layer 200, an encapsulation layer 300, and an optical layer 400. The display device DD may include a display area DA and a non-display area NDA around (e.g., surrounding) the display area DA, and the emission element layer 200 may be within the display area DA. The display device DD may further include a display panel, a window on the display panel, and/or an outer casing below the display panel.

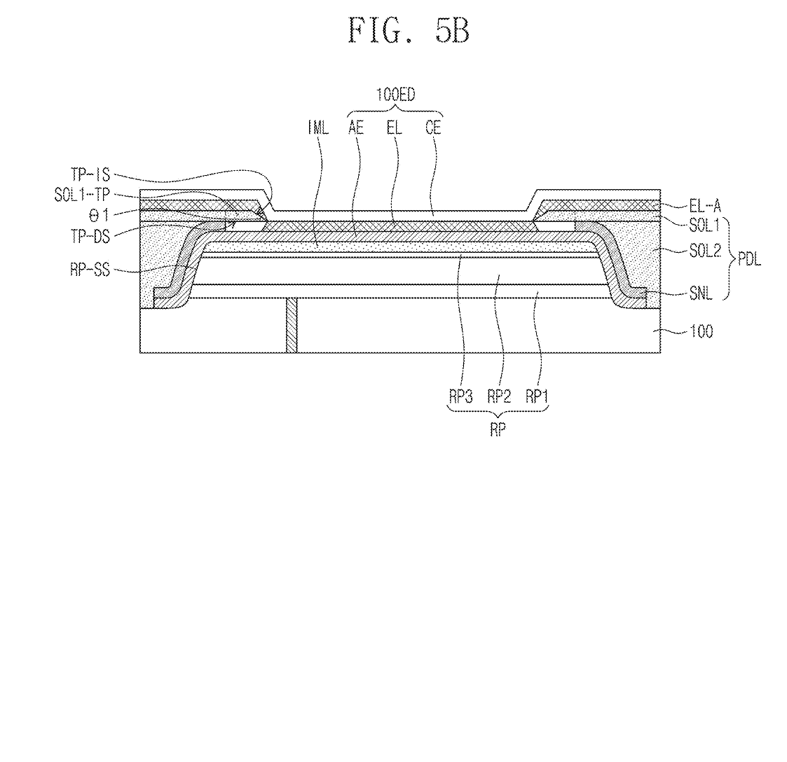

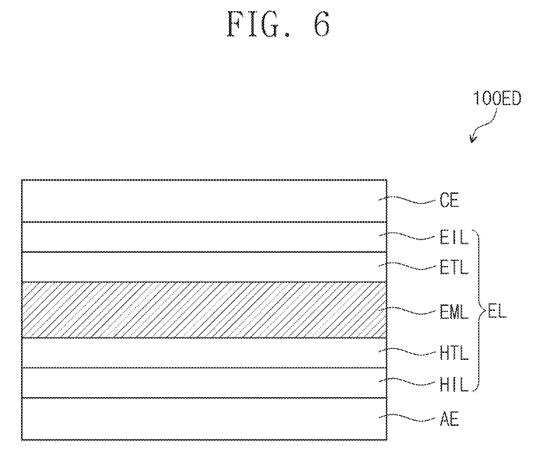

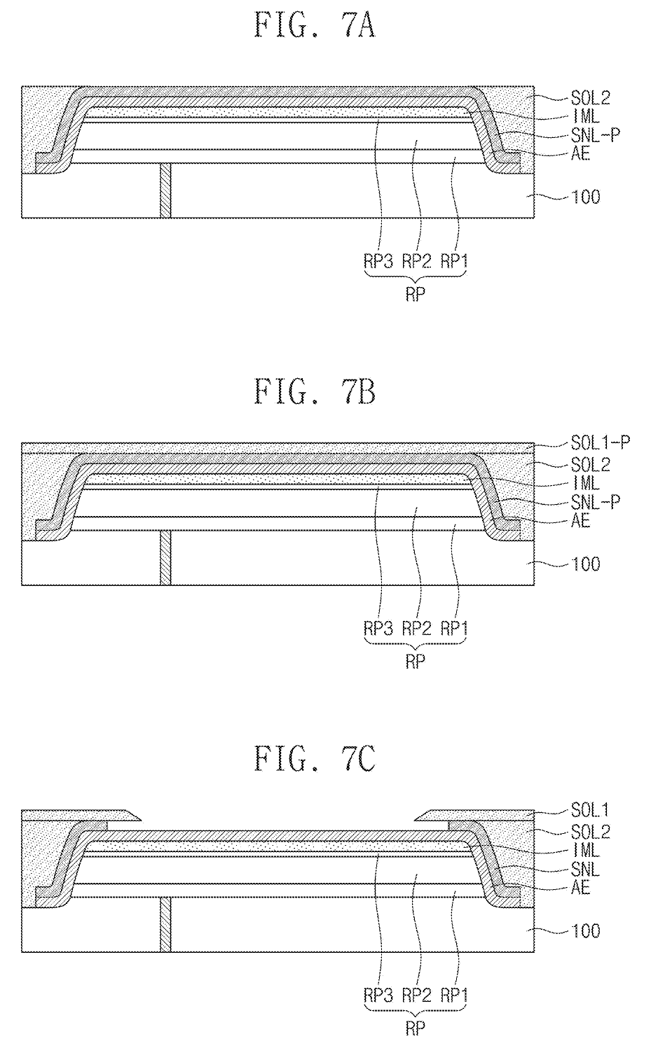

FIG. 5A illustrates a cross-sectional view showing a display panel DP according to one or more embodiments of the present disclosure. FIG. 5B illustrates an enlarged cross-sectional view showing the display panel DP according to one or more embodiments of the present disclosure. FIG. 6 illustrates a simplified enlarged cross-sectional view showing an emission element 100ED according to one or more embodiments of the present disclosure.

The semiconductor circuit substrate 100 may include a complementary metal oxide semiconductor (CMOS) wafer. The CMOS wafer may include an nMOSFET (NMOS) and a pMOSFET (PMOS) that are complementarily connected. A plurality of pixel regions may be regularly arranged on the CMOS wafer, and a pixel circuit 100PC may be on each pixel region.

The semiconductor circuit substrate 100 may include a base substrate 110 and the pixel circuit 100PC on the base substrate 110. The base substrate 110 may be a silicon substrate, a germanium substrate, and/or a silicon-on-insulator (SOI) substrate. For example, the base substrate 110 may be a monocrystalline silicon substrate, but the present disclosure is not particularly limited thereto.

The pixel circuit 100PC may control the operation of an emission element included in the emission element layer 200. The pixel circuit 100PC may include at least one transistor. The pixel circuit 100PC may include a gate electrode E1 on the base substrate 110, a gate dielectric pattern GIL between the gate electrode E1 and the base substrate 110, and source/drain regions E2 and E3 on opposite sides of the gate electrode E1. The source/drain regions E2 and E3 may be impurity doped regions formed in the base substrate 110 on opposite sides of the gate electrode E1.

The gate electrode E1 may include a doped semiconductor material, a conductive metal nitride (e.g., an electrically conductive metal nitride such as, for example, titanium nitride and/or tantalum nitride), a metal (e.g., aluminum and/or tungsten), or a combination thereof. The gate dielectric pattern GIL may include silicon oxide. The source/drain regions E2 and E3 may each have a conductivity different from that of the base substrate 110. The source/drain regions E2 and E3 may each include n-type impurities (e.g., phosphorus (P) and/or arsenic (As)) or p-type impurities (e.g., boron (B)).

The base substrate 110 may be provided thereon with a lower interlayer dielectric layer 120 that covers the pixel circuit 100PC. The lower interlayer dielectric layer 120 may include an oxide layer, a nitride layer, and/or an oxynitride layer. The lower interlayer dielectric layer 120 may be provided thereon with lower conductive contacts 130 (e.g., lower electrically conductive contacts 130) that are correspondingly connected to the source/drain regions E2 and E3. The lower conductive contacts 130 may include a conductive material (e.g., an electrically conductive material).

Line patterns 140 may be provided on the lower interlayer dielectric layer 120. Each of the lower conductive contacts 130 may be connected to a corresponding one of the line patterns 140. The line patterns 140 may include, for example, metal. Additional line patterns may be provided between the lower interlayer dielectric layer 120 and the line patterns 140. In one or more embodiments, each of the lower conductive contacts 130 may be electrically connected to a corresponding one of the line patterns 140 through one or more corresponding additional line patterns. The additional line patterns may include, for example, metal.

The lower interlayer dielectric layer 120 may be provided thereon with an upper interlayer dielectric layer 150 that covers the line patterns 140. The upper interlayer dielectric layer 150 may include an oxide layer, a nitride layer, and/or an oxynitride layer.

The emission element layer 200 may include an emission element 100ED electrically connected to the pixel circuit 100PC. The emission element layer 200 may be on the semiconductor circuit substrate 100. FIG. 5A representatively depicts one emission element 100ED. In one or more embodiments, the emission element 100ED may include an organic light-emitting element, but the present disclosure is not limited thereto. The emission element 100ED may produce a first color light, a second color light, and a third color light. The first color light, the second color light, and the third color light may be mixed to create a white color light. The present disclosure, however, is not limited thereto, and the emission element 100ED may produce only the first color light. An emission area PXA may be defined to correspond to the emission element 100ED. The emission area PXA may be defined by an emission opening PDL-OP provided in a pixel definition layer PDL.

The emission element 100ED may include a first electrode AE, an emission unit EL, and a second electrode CE. The first electrode AE may be referred to as either a pixel electrode or an anode, and the second electrode CE may be referred to as either a common electrode or a cathode. The emission unit EL may include a functional layer that is commonly provided on the emission areas PXA and an emission layer that is patterned (e.g., selectively patterned) corresponding to each of the emission areas PXA.

The first electrode AE may be on the semiconductor circuit substrate 100. The first electrode AE may be connected to one of the line patterns 140 through an upper conductive contact 160 (e.g., an upper electrically conductive contact 160) that penetrates the upper interlayer dielectric layer 150. The first electrode AE may be a transmissive electrode, a transflective electrode, or a reflective electrode. In one or more embodiments, the first electrode AE may include a reflective layer formed of magnesium, aluminum, platinum, palladium, gold, nickel, neodymium, iridium, chromium, or a combination thereof, and also include a transparent or translucent electrode layer formed on the reflective layer. The transparent or translucent electrode layer may include indium-tin oxide, indium-zinc oxide, indium-gallium-zinc oxide, zinc oxide, indium oxide, aluminum doped zinc oxide, or a combination thereof. For example, the first electrode AE may have a multi-layered structure in which indium-tin oxide, silver, and indium-tin oxide are sequentially stacked.

A reflective conductive pattern RP (e.g., a reflective electrically conductive pattern RP) may be on the semiconductor circuit substrate 100. The reflective conductive pattern RP may be placed on the upper interlayer dielectric layer 150 and electrically connected through the upper conductive contact 160 to the pixel circuit 100PC. The reflective conductive pattern RP may have a multi-layered structure in which reflective layers are sequentially stacked. For example, the reflective conductive pattern RP may include a first reflective layer RP1, a second reflective layer RP2 on the first reflective layer RP1, and a third reflective layer RP3 on the second reflective layer RP2. The first reflective layer RP1 may be on the semiconductor circuit substrate 100 and connected through the upper conductive contact 160 to a corresponding one of the line patterns 140.

The first reflective layer RP1 may be formed of copper (Cu), aluminum (Al), tungsten (W), molybdenum (Mo), chromium (Cr), gold (Au), titanium (Ti), nickel (Ni), neodymium (Nd), and/or an alloy including a combination thereof. For example, the first reflective layer RP1 may include titanium (Ti) and/or titanium nitride (TiN).

The second reflective layer RP2 may be formed of copper (Cu), aluminum (Al), tungsten (W), molybdenum (Mo), chromium (Cr), gold (Au), titanium (Ti), nickel (Ni), neodymium (Nd), and/or an alloy including a combination thereof. For example, the second reflective layer RP2 may include aluminum (Al).

The third reflective layer RP3 may be formed of copper (Cu), aluminum (Al), tungsten (W), molybdenum (Mo), chromium (Cr), gold (Au), titanium (Ti), nickel (Ni), neodymium (Nd), and/or an alloy including a combination thereof. For example, the third reflective layer RP3 may include titanium nitride (TiN).

The second reflective layer RP2 may substantially reflect light from the emission element 100ED. A thickness of the second reflective layer RP2 may be greater than that of each of the first reflective layer RP1 and the third reflective layer RP3. For example, the thickness of the second reflective layer RP2 may be in a range from about 500 Å to about 1,000 Å, and the thickness of each of the first reflective layer RP1 and the third reflective layer RP3 may be in a range from about 80 Å to about 150 Å.

In one or more embodiments of the present disclosure, an interlayer dielectric layer IML may be on the third reflective layer RP3 positioned at the top of the reflective conductive pattern RP. The interlayer dielectric layer IML may be between the reflective conductive pattern RP and the first electrode AE. Thus, the first electrode AE may not be in direct contact with a top surface of the reflective conductive pattern RP, and may be in contact with a lateral surface of the reflective conductive pattern RP.

A pixel definition layer PDL may be on the semiconductor circuit substrate 100. The pixel definition layer PDL may have an emission opening PDL-OP that exposes a portion of the first electrode AE. For example, the pixel definition layer PDL may cover an edge of the first electrode AE. The pixel definition layer PDL may define the emission area PXA. The pixel definition layer PDL may have a single-layered or multi-layered structure.

The emission unit EL may be on the first electrode AE. A peripheral emission unit EL-A may be located on the pixel definition layer PDL. The second electrode CE may be placed on the emission unit EL and also on the peripheral emission unit EL-A.

The emission element layer 200 may further include a capping layer CPL on the second electrode CE. The capping layer CPL may serve to utilize the principle of constructive interference to increase emission efficiency. For example, the capping layer CPL may include a material whose refractive index is equal to or greater than about 1.6 with respect to light having a wavelength of about 589 nm. The capping layer CPL may be an organic capping layer including an organic material, an inorganic capping layer including an inorganic material, or a composite capping layer (e.g., a composite capping layer including organic and inorganic materials). For example, the capping layer CPL may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be selectively replaced with a substituent including oxygen (O), nitrogen (N), sulfur (S), selenium (Se), silicon (Si), fluorine (F), chlorine (Cl), bromine (Br), iodine (I), or any combination thereof.

The encapsulation layer 300 may be on the emission element layer 200. The encapsulation layer 300 may include a first inorganic encapsulation layer 310, an organic encapsulation layer 320, and a second inorganic encapsulation layer 330 that are sequentially stacked. The first and second inorganic encapsulation layers 310 and 330 may protect the emission element layer 200 against moisture and oxygen, and the organic encapsulation layer 320 may protect the emission element layer 200 against foreign substances, such as dust particles and the like.

The optical layer 400 may be on the encapsulation layer 300. The optical layer 400 may include a division layer 410, a plurality of color filters 420, a cover layer 430, and a lens pattern 440.

A material included in the division layer 410 is not particularly limited as long as the material absorbs light. The division layer 410 may be a black color layer, and in one or more embodiments, the division layer 410 may include a black coloring agent. The black coloring agent may include a black dye and/or a black pigment. The black coloring agent may include carbon black, metal such as chromium, and/or an oxide thereof.

The color filter 420 may correspond to an opening defined in the division layer 410. The color filter 420 may be transparent to light which is provided from the emission unit EL that overlaps the color filter 420. The color filter 420 may increase color reproducibility of light provided from the emission unit EL.

The cover layer 430 may cover the color filter 420. The cover layer 430 may include an organic material, but the present disclosure is not particularly limited thereto. The lens pattern 440 may be arranged on a region that overlaps a portion of the emission opening PDL-OP of the pixel definition layer PDL. The shape of the lens pattern 440, however, is not particularly limited thereto. The cover layer 430 and the lens pattern 440 may include the same material and may have a single unitary shape.

In this description, the phrase “a component is directly on another component” means that there is no third component between the component and the another component, and that the component and the another component are in contact with each other. Moreover, the expression of “direct contact” indicates that individual surfaces of components are in direct contact with each other.

Referring to FIG. 5B, the pixel definition layer PDL may include a silicon nitride layer SNL directly on the first electrode AE and a silicon oxide layer SOL1 directly on the silicon nitride layer SNL.

Referring together to FIGS. 5A and 5B, the emission element layer 200 may further include an interlayer dielectric layer IML between the reflective conductive pattern RP and the first electrode AE. The interlayer dielectric layer IML may include the same material as that of the silicon oxide layer SOL1. For example, the interlayer dielectric layer IML may include silicon oxide (SiO₂). Thickness of the interlayer dielectric layer IML may be adjusted to increase reflection efficiency of light. For example, a refractive index of the interlayer dielectric layer IML may be adjusted to reduce optical interference, and thus a display device may improve in emission properties.

The first electrode AE may be around (e.g., surround) the interlayer dielectric layer IML and the reflective conductive pattern RP. The first electrode AE may be in contact with a lateral surface RP-SS of the reflective conductive pattern RP and thus electrically connected to the semiconductor circuit substrate 100. A distal end of the first electrode AE may be on the semiconductor circuit substrate 100.

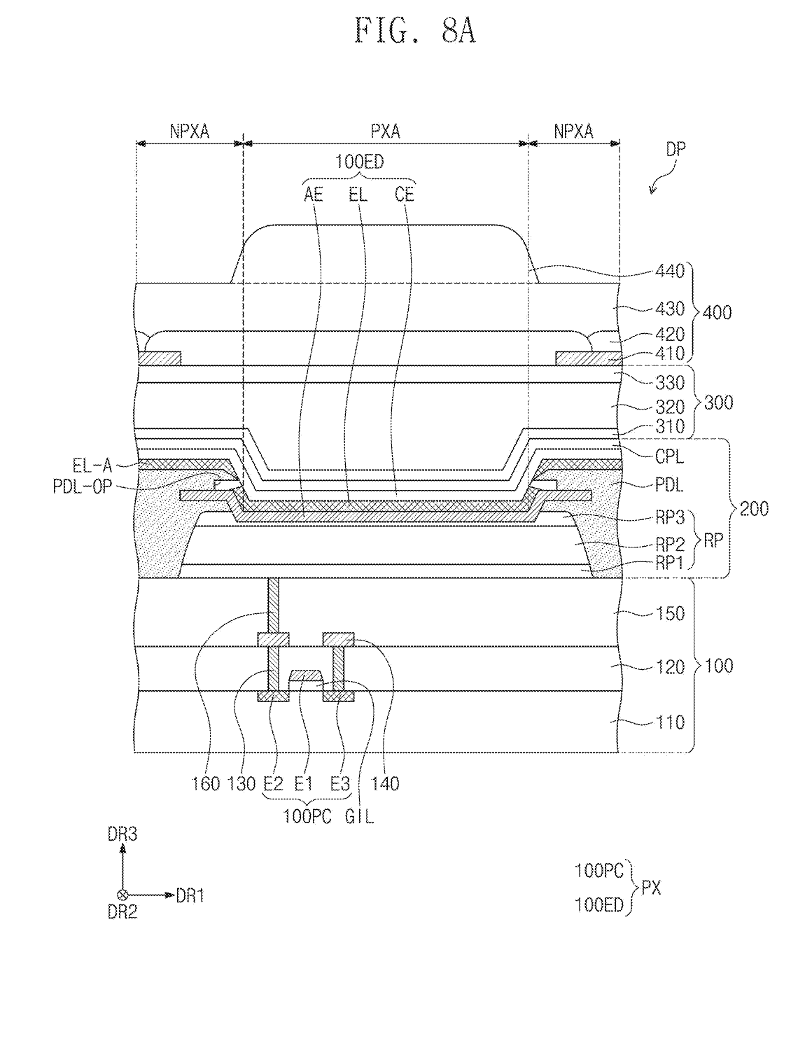

The silicon nitride layer SNL may be around (e.g., surround) a portion of the first electrode AE. The silicon nitride layer SNL may be around (e.g., surround) a lateral surface of the first electrode AE. The silicon nitride layer SNL may be patterned (e.g., selectively patterned) through the following processes of FIGS. 7A-7C. The silicon nitride layer SNL may include silicon nitride (Si₃N₄ or SiNₓ), whose composition is differentiated depending on process conditions.

In one or more embodiments, a thickness of the silicon nitride layer SNL may be in a range from about 50 Å to about 100 Å. The thickness of the silicon nitride layer SNL may be less than that of the silicon oxide layer SOL1. A reduction in thickness of the silicon nitride layer SNL may facilitate etching in an isotropic wet etching process. Therefore, a tip structure SOL1-TP of the silicon oxide layer SOL1 may be easily formed.

In one or more embodiments, the pixel definition layer PDL may further include a lower silicon oxide layer SOL2 between the silicon oxide layer SOL1 and the semiconductor circuit substrate 100. On the semiconductor circuit substrate 100, the lower silicon oxide layer SOL2 may be around (e.g., surround) the silicon nitride layer SNL. The silicon oxide layer SOL1 in FIGS. 5A and 5B may be referred to an upper silicon oxide layer SOL1. The lower silicon oxide layer SOL2 may include the same material as that of the upper silicon oxide layer SOL1. For example, each of the lower silicon oxide layer SOL2 and the upper silicon oxide layer SOL1 may include silicon oxide (SiO₂). The upper silicon oxide layer SOL1 may be deposited after the lower silicon oxide layer SOL2 undergoes a planarization process. A maximum thickness of the lower silicon oxide layer SOL2 may be greater than that of the upper silicon oxide layer SOL1.

When viewed in plan (e.g., in a plan view), the upper silicon oxide layer SOL1 may define a tip structure SOL1-TP that protrudes more inward from the emission opening PDL-OP than the silicon nitride layer SNL. For example, the tip structure SOL1-TP of the upper silicon oxide layer SOL1 may indicate a tip portion that protrudes from the silicon nitride layer SNL toward the emission opening PDL-OP. The tip structure SOL1-TP may be defined to refer to a portion that is spaced and/or apart (e.g., spaced apart or separated) from a top surface of the first electrode AE and does not overlap the silicon nitride layer SNL.

In one or more embodiments, the tip structure SOL1-TP may have a bottom surface TP-DS that faces the first electrode AE and an inclined surface TP-IS that corresponds to a lateral surface thereof. The inclined surface TP-IS of the tip structure SOL1-TP may form an inclination angle relative to the bottom surface TP-DS. The inclination angle of the inclined surface TP-IS of the tip structure SOL1-TP may form an acute angle θ1 relative to the bottom surface TP-DS. The acute angle θ1 of the tip structure SOL1-TP may be in a range from about 30° to about 60°.

According to one or more embodiments of the present disclosure, the peripheral emission unit EL-A may be directly on the upper silicon oxide layer SOL1. For example, the peripheral emission unit EL-A may be directly on the tip structure SOL1-TP of the upper silicon oxide layer SOL1. The peripheral emission unit EL-A and the emission unit EL may be electrically separated from each other through the tip structure SOL1-TP. As the peripheral emission unit EL-A and the emission unit EL are electrically separated from each other, a path of lateral current of the emission element 100ED may be interrupted. Therefore, it may be possible to reduce lateral leakage current and to increase emission efficiency and emission uniformity.

Referring to FIG. 6, the emission element 100ED may include the first electrode AE and may also include the emission unit EL and the second electrode CE that are on the first electrode AE. The peripheral emission unit (see EL-A of FIG. 5B) may have the same stack structure as that of the emission unit EL.

The emission unit EL may include a hole injection layer HIL on the first electrode AE, a hole transport layer HTL on the hole injection layer HIL, an emission layer EML on the hole transport layer HTL, an electron transport layer ETL on the emission layer EML, and an electron injection layer EIL on the electron transport layer ETL.

The hole injection layer HIL may include a hole injection material doped with p-type impurities. The hole injection layer HIL may help inject holes from the first electrode AE into the emission layer EML. The hole transport layer HTL may include a hole transport material doped with p-type impurities. The hole transport layer HTL may transport holes injected from the hole injection layer HIL to the emission layer EML. The electron transport layer ETL may include an electron transport material including metal, and the electron injection layer EIL may include an electron injection material including metal. The electron injection layer EIL may help inject electrons from the second electrode CE into the emission layer EML. Likewise, the electron transport layer ETL may transport electrons injected from the electron injection layer EIL to the emission layer EML. The emission layer EML may produce a first color light, a second color light, and a third color light. The first color light may be a red light, the second color light may be a green light, and the third color light may be a blue light.

Referring to FIGS. 5B and 6, the hole injection layer HIL may have an electrical conductivity greater than those of other layers included in the emission unit EL. The tip structure SOL1-TP may electrically disconnect the hole injection layer HIL of the emission unit EL directly on the first electrode AE from the hole injection layer HIL of the peripheral emission unit EL-A on the upper silicon oxide layer SOL1. Therefore, it may be possible to reduce an unnecessary lateral leakage current between adjacent emission elements 100ED.

The second electrode CE on the emission unit EL may further extend onto the peripheral emission unit EL-A. The second electrode CE may have a single unitary shape on the emission unit EL and the peripheral emission unit EL-A. As illustrated in FIG. 5B, as the upper silicon oxide layer SOL1 having the tip structure SOL1-TP is on the silicon nitride layer SNL, the pixel definition layer PDL may decrease in total thickness. Therefore, the second electrode CE on the peripheral emission unit EL-A and the emission unit EL may be suppressed or reduced from the occurrence of disconnection caused by the thickness of the pixel definition layer PDL.

FIGS. 7A-7C illustrate cross-sectional views partially showing a method of fabricating a display panel according to one or more embodiments of the present disclosure. In the following description, the same reference numerals are allocated to the same components as those discussed above, and their explanations will not be provided.

Referring to FIG. 7A, there are illustrated a semiconductor circuit substrate 100 and a first electrode AE that is around (e.g., surrounds) a reflective conductive pattern RP (e.g., a reflective electrically conductive pattern RP) and an interlayer dielectric layer IML on the semiconductor circuit substrate 100. FIG. 7A depicts a structure in which the first electrode AE is provided thereon with a preliminary silicon nitride layer SNL-P that is around (e.g., surrounds) the first electrode AE and with a lower silicon oxide layer SOL2 that covers the semiconductor circuit substrate 100. The preliminary silicon nitride layer SNL-P and the lower silicon oxide layer SOL2 depicted in FIG. 7A may undergo a planarization process, such as a chemical mechanical polishing (CMP) process, to form a planarized layer.

Referring to FIG. 7B, a preliminary upper silicon oxide layer SOL1-P may be deposited on the planarized layer formed from each of the preliminary silicon nitride layer SNL-P and the lower silicon oxide layer SOL2.

Referring to FIG. 7C, a photolithography process may be employed such that the preliminary silicon nitride layer SNL-P and the preliminary upper silicon oxide layer SOL1-P of FIG. 7B may be patterned (e.g., selectively patterned) to form a silicon nitride layer SNL and an upper silicon oxide layer SOL1, respectively. The silicon nitride layer SNL, the upper silicon oxide layer SOL1, and the lower silicon oxide layer SOL2 may constitute a pixel definition layer PDL (see FIG. 5B). When an isotropic wet etching process is used for patterning, an undercut may be formed more in the silicon nitride layer SNL than in the upper silicon oxide layer SOL1. In the etching process for the preliminary silicon nitride layer SNL-P and the preliminary upper silicon oxide layer SOL1-P, the first electrode AE may not be etched because it has a different etch selectivity from the pixel definition layer PDL. An etching gas for silicon oxide and silicon nitride is a fluorine-based gas, whereas an etching gas for the first electrode AE including indium oxide is a chlorine-based gas, and thus the first electrode AE and the pixel definition layer PDL may differ in terms of etch selectivity.

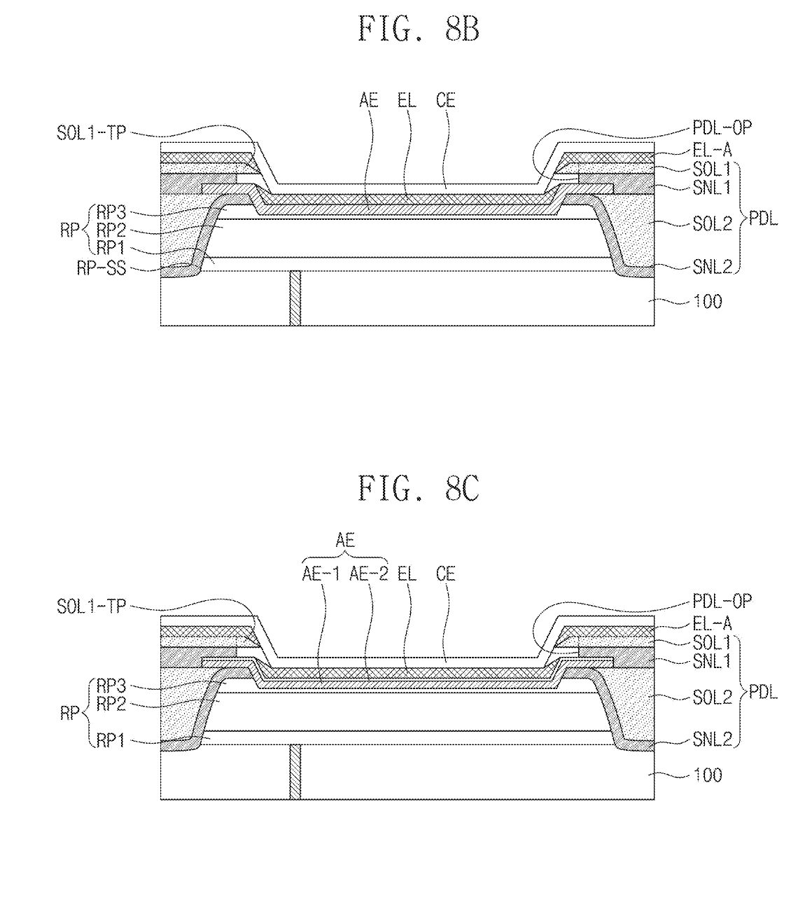

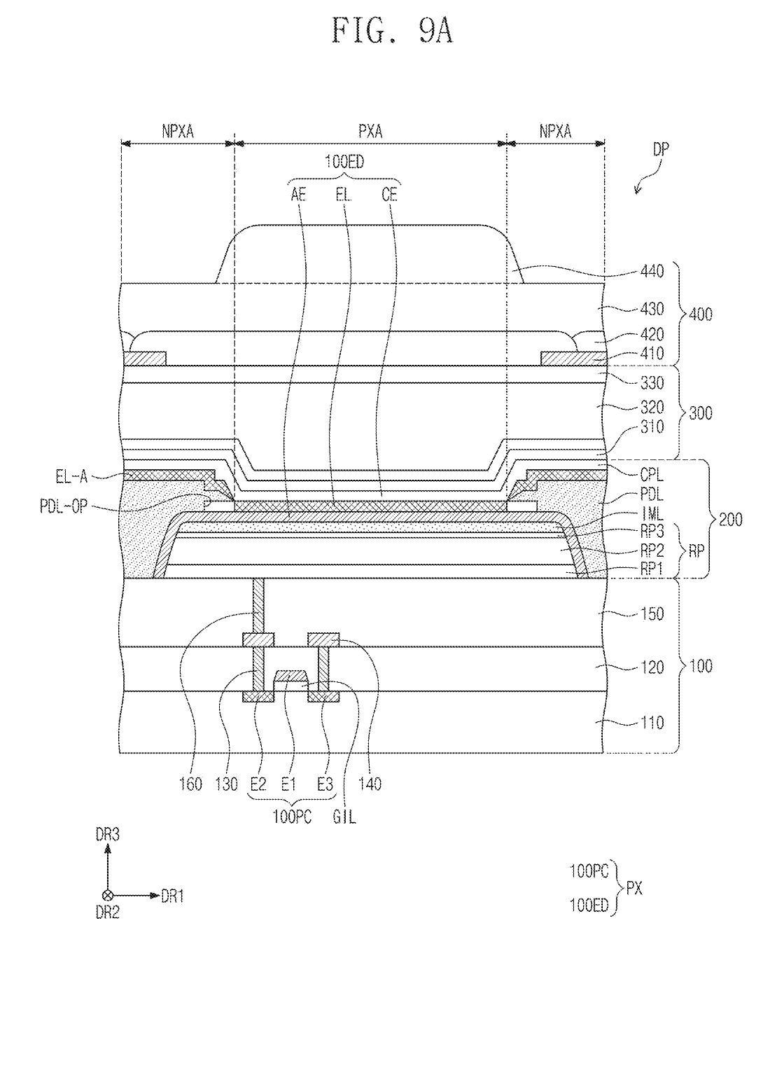

FIG. 8A illustrates a cross-sectional view showing a display panel DP according to one or more embodiments of the present disclosure. FIGS. 8B and 8C illustrate enlarged cross-sectional views showing display panels DP according to one or more embodiments of the present disclosure. In the following description, the same reference numerals are allocated to the same components as those discussed in FIGS. 5A and 5B, and their duplicate explanations will not be provided.

In comparison with FIG. 5A, the interlayer dielectric layer (see IML of FIG. 5A) may not be provided in FIG. 8A. Thus, the first electrode AE may be in contact with a top surface of the third reflective layer RP3. In addition, the third reflective layer RP3 may be patterned (e.g., selectively patterned) to have a cavity or groove that is inwardly recessed on a central portion thereof.

Referring to FIG. 8B, the pixel definition layer PDL may further include a silicon nitride layer SNL2 in contact with a lateral surface RP-SS of the reflective conductive pattern RP. In FIG. 8B, a silicon nitride layer below the first electrode AE may be referred to as a lower silicon nitride layer SNL2, and a silicon nitride layer above the first electrode AE may be referred to as an upper silicon nitride layer SNL1. The upper silicon nitride layer SNL1 and the lower silicon nitride layer SNL2 may include the same material. The first electrode AE may extend inwardly toward the upper silicon nitride layer SNL1, and a portion of the upper silicon nitride layer SNL1 may overlap a portion of the first electrode AE.

In one or more embodiments, the pixel definition layer PDL may further include a lower silicon oxide layer SOL2 that is between the upper silicon nitride layer SNL1 and the semiconductor circuit substrate 100 and is around (e.g., surrounds) the lower silicon nitride layer SNL2. A silicon oxide layer on a top surface of the upper silicon nitride layer SNL1 may be referred to as an upper silicon oxide layer SOL1, and a silicon oxide layer on a bottom surface of the upper silicon nitride layer SNL1 may be referred to as a lower silicon oxide layer SOL2. The upper silicon oxide layer SOL1 and the lower silicon oxide layer SOL2 may include the same material.

Referring to FIG. 8C, the first electrode AE may include a 1-1^{st} electrode AE-1 directly on the reflective conductive pattern RP and a 1-2^{nd} electrode AE-2 on the 1-1^{st} electrode AE-1. The 1-1^{st} electrode AE-1 may include a transparent or translucent electrode layer. For example, the 1-1^{st} electrode AE-1 may include a transparent conductive oxide selected from indium-tin oxide, indium-zinc oxide, indium-gallium-zinc oxide, zinc oxide, indium oxide, aluminum doped zinc oxide, or a combination thereof. The 1-2^{nd} electrode AE-2 may include a conductive metal nitride (e.g., an electrically conductive metal nitride). For example, the 1-2^{nd} electrode AE-2 may include titanium nitride. A thickness of the 1-2^{nd} electrode AE-2 may be in a range from about 10 Å to about 20 Å.

As the 1-2^{nd} electrode AE-2 is on the 1-1^{st} electrode AE-1, a top surface of the 1-1^{st} electrode AE-1 and the upper silicon nitride layer SNL1 may not be in direct contact with each other. As the 1-2^{nd} electrode AE-2 protects the top surface of the 1-1^{st} electrode AE-1, it may be possible to prevent or reduce the occurrence of precipitation of indium (In) in the 1-1^{st} electrode AE-1 caused by hydrogen reduction in a photolithography process. The precipitation of indium (In) may be suppressed to reduce an indium protrusion that occurs at an interface of the 1-1^{st} electrode AE-1, and thus a resistance (e.g., electrical resistance) may decrease to achieve uniformity of electrical conductivity. Although the 1-2^{nd} electrode AE-2 is included, an optical reflectivity may be maintained at the same level as that of FIG. 8B in which the 1-2^{nd} electrode AE-2 is not included.

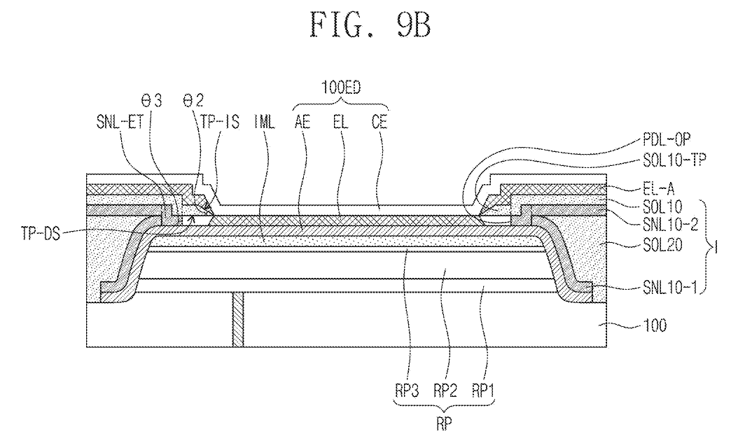

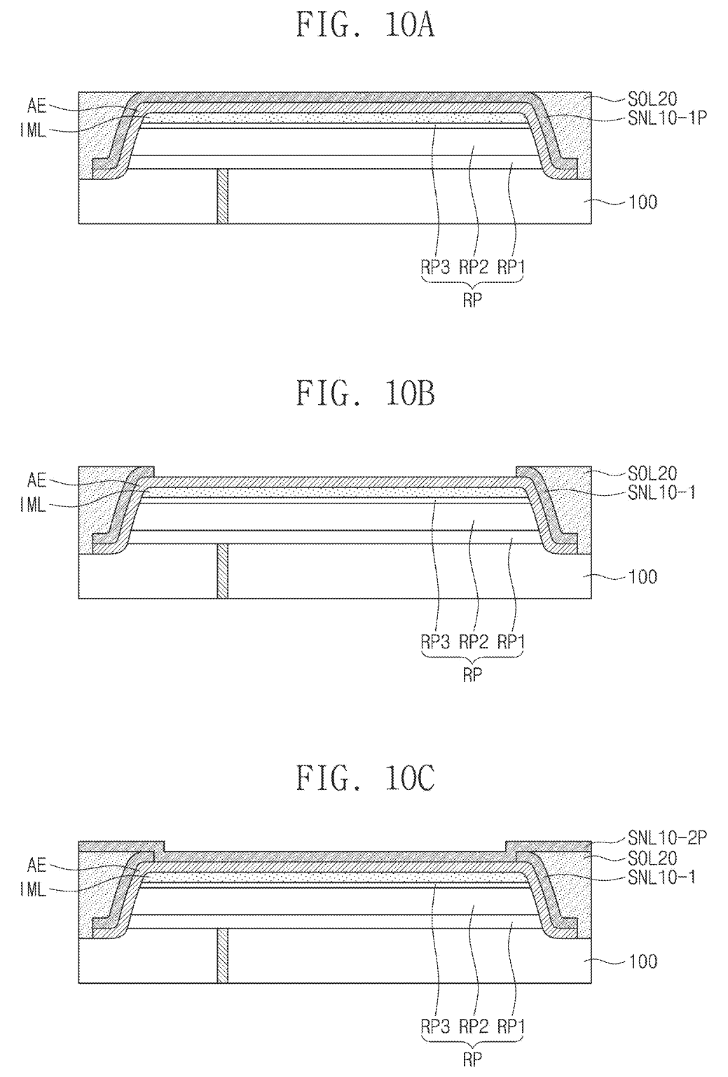

FIG. 9A illustrates a cross-sectional view showing a display panel DP according to one or more embodiments of the present disclosure. FIG. 9B illustrates an enlarged cross-sectional view showing the display panel DP according to one or more embodiments of the present disclosure. In FIGS. 9A and 9B, the same reference numerals are allocated to the same components as those discussed in FIGS. 5A and 5B, and their duplicate explanations will not be provided.

Referring to FIGS. 9A and 9B, the pixel definition layer PDL may include a 1-1^{st} silicon nitride layer SNL10-1 directly on the first electrode AE, a 1-2^{nd} silicon nitride layer SNL10-2 on the 1-1^{st} silicon nitride layer SNL10-1, and a silicon oxide layer SOL10 directly on the 1-2^{nd} silicon nitride layer SNL10-2. When viewed in plan (e.g., in a plan view), the 1-2^{nd} silicon nitride layer SNL10-2 may include a protrusion SNL-ET that protrudes more inward from the emission opening PDL-OP than the 1-1^{st} silicon nitride layer SNL10-1.

When viewed in plan (e.g., in a plan view), the silicon oxide layer SOL10 may define a tip structure SOL10-TP that protrudes more inward from the emission opening PDL-OP than the protrusion SNL-ET of the 1-1^{st} silicon nitride layer SNL10-1.

In this description, the protrusion SNL-ET of the 1-1^{st} silicon nitride layer SNL10-1 may indicate a portion in contact with the first electrode AE, whereas the tip structure SOL10-TP of the silicon oxide layer SOL10 may denote a portion that is spaced and/or apart (e.g., spaced apart or separated) from the first electrode AE, that does not overlap the protrusion SNL-ET, and that protrudes more inward from the emission opening PDL-OP.

In one or more embodiments, the pixel definition layer PDL may further include a silicon oxide layer SOL20 between the 1-1^{st} silicon nitride layer SNL10-1 and the 1-2^{nd} silicon nitride layer SNL10-2. The silicon oxide layer SOL20 may be between the semiconductor circuit substrate 100 and the 1-2^{nd} silicon nitride layer SNL10-2. Referring to FIG. 9B, the silicon oxide layer SOL10 on the 1-2^{nd} silicon nitride layer SNL10-2 may be referred to as an upper silicon oxide layer SOL10, and the silicon oxide layer SOL20 between the 1-1^{st} silicon nitride layer SNL10-1 and the 1-2^{nd} silicon nitride layer SNL10-2 may be referred to as a lower silicon oxide layer SOL20. The lower silicon oxide layer SOL20 may include the same material as that of the upper silicon oxide layer SOL10.

In one or more embodiments, a protrusion SNL-ET of the 1-1^{st} silicon nitride layer SNL10-1 may provide a step difference. A portion of the protrusion SNL-ET may be bent at a right angle and a step difference may be formed upward. A portion of the upper silicon oxide layer SOL10 may be on the step difference and may have a shape that compensates or supplements the step difference. The peripheral emission unit EL-A, which is on a tip structure SOL10-TP of the upper silicon oxide layer SOL10, may overlap the step difference, thereby also forming a step difference.

In one or more embodiments, the tip structure SOL10-TP may have a bottom surface TP-DS and an inclined surface TP-IS. The inclined surface TP-IS of the tip structure SOL10-TP may form an acute angle θ2 relative to the bottom surface TP-DS of the tip structure SOL10-TP, and an angle θ3 formed between an inner lateral surface of the protrusion SNL-ET of the 1-1^{st} silicon nitride layer SNL10-1 and a top surface of the first electrode AE may be greater than the acute angle θ2. For example, a right angle may be given as the angle θ3 formed between the inner lateral surface of the protrusion SNL-ET of the 1-1^{st} silicon nitride layer SNL10-1 and the top surface of the first electrode AE.

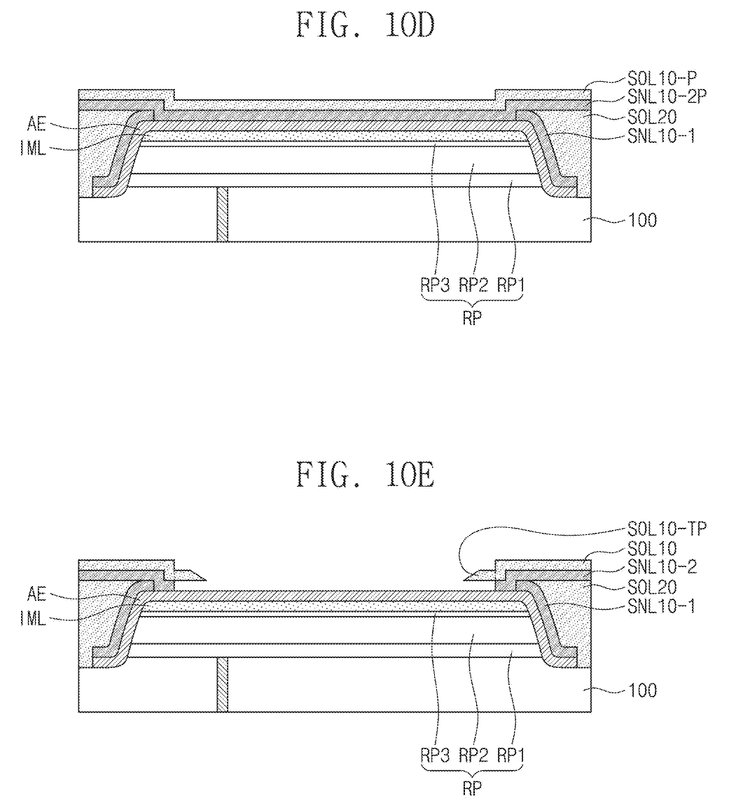

FIGS. 10A-10E illustrate cross-sectional views partially showing a method of fabricating a display panel according to one or more embodiments of the present disclosure.

Referring to FIG. 10A, there are illustrated a semiconductor circuit substrate 100 and a first electrode AE that is around (e.g., surrounds) a reflective conductive pattern RP (e.g., a reflective electrically conductive pattern RP) and an interlayer dielectric layer IML on the semiconductor circuit substrate 100. FIG. 10A depicts a structure in which the first electrode AE is provided thereon with a preliminary 1-1^{st} silicon nitride layer SNL10-1P that is around (e.g., surrounds) the first electrode AE and with a lower silicon oxide layer SOL20 that covers the semiconductor circuit substrate 100. The preliminary 1-1^{st} silicon nitride layer SNL10-1P and the lower silicon oxide layer SOL20 depicted FIG. 10A may undergo a planarization process, such as a chemical mechanical polishing (CMP) process, to form a planarized layer.

Referring to FIG. 10B, the preliminary 1-1^{st} silicon nitride layer SNL10-1P of FIG. 10A may be patterned (e.g., selectively patterned) through a photolithography process. As one of the first electrode AE and the preliminary 1-1^{st} silicon nitride layer SNL10-1P has an etch selectivity different from that of the other, only the preliminary 1-1^{st} silicon nitride layer SNL10-1P may be etched to form a 1-1^{st} silicon nitride layer SNL10-1 through which a top surface of the first electrode AE is partially exposed.

Referring to FIG. 10C, a preliminary 1-2^{nd} silicon nitride layer SNL10-2P may be deposited on the 1-1^{st} silicon nitride layer SNL10-1 and the lower silicon oxide layer SOL20. A thickness of the preliminary 1-2^{nd} silicon nitride layer SNL10-2P may be in a range from about 50 Å to about 100 Å. The preliminary 1-2^{nd} silicon nitride layer SNL10-2P may have a step difference that is formed by patterning of the 1-1^{st} silicon nitride layer SNL10-1 depicted in FIG. 10B.

Referring to FIG. 10D, a preliminary upper silicon oxide layer SOL10-P may be deposited on the preliminary 1-2^{nd} silicon nitride layer SNL10-2P. A thickness of the preliminary upper silicon oxide layer SOL10-P may be greater than that of the preliminary 1-2^{nd} silicon nitride layer SNL10-2P. Likewise, the preliminary 1-2^{nd} silicon nitride layer SNL10-2P of FIG. 10C may be patterned (e.g., selectively patterned) to form a step difference.

Referring to FIG. 10E, a photolithography process may be employed such that the preliminary upper silicon oxide layer SOL10-P and the preliminary 1-2^{nd} silicon nitride layer SNL10-2P of FIG. 10D may be patterned (e.g., selectively patterned) to form an upper silicon oxide layer SOL10 and a 1-2^{nd} silicon nitride layer SNL10-2, respectively. A reduction in thickness of the 1-2^{nd} silicon nitride layer SNL10-2 may facilitate etching in an isotropic wet etching process. Therefore, a tip structure SOL10-TP of the upper silicon oxide layer SOL10 may be easily formed.

According to embodiments of the present disclosure, a pixel definition layer may include a silicon nitride layer directly on a first electrode and a silicon oxide layer directly on the silicon nitride layer. The silicon oxide layer may include a tip structure, and a peripheral emission unit directly on the pixel definition layer may be electrically separated from an emission unit on the first electrode, which may reduce a lateral leakage current.

In addition, a total thickness of the pixel definition layer may decrease to allow a second electrode to have a shape that extends on the peripheral emission unit and the emission unit. Consequently, the second electrode may be suppressed from the occurrence of electrical disconnection.

Although embodiments have been described with reference to several illustrative examples thereof, it will be understood by those of ordinary skill in the art that various suitable changes in form and details may be made without departing from the spirit and scope of the present disclosure as set forth in the following claims, and equivalents thereof.

Thus, the technical scope of the present disclosure is not limited by the embodiments and examples described in more detail above, but by the following claims, and equivalents thereof.

What is claimed is:

1. A display device, comprising:
a semiconductor circuit substrate comprising a pixel circuit;
a reflective conductive pattern on the semiconductor circuit substrate;
an emission element comprising a first electrode in contact with the reflective conductive pattern, an emission unit on the first electrode, and a second electrode on the emission unit, the emission element being on the semiconductor circuit substrate;
a pixel definition layer on the semiconductor circuit substrate and having an emission opening that exposes the first electrode; and
a peripheral emission unit on the pixel definition layer,
wherein the pixel definition layer comprises:
a silicon nitride layer directly on the first electrode; and
a silicon oxide layer directly on the silicon nitride layer,
wherein the silicon oxide layer defines a tip structure that protrudes more inward from the emission opening than the silicon nitride layer, and
wherein the peripheral emission unit is directly on the silicon oxide layer and electrically separated through the tip structure from the emission unit.

2. The display device of claim 1, further comprising an interlayer dielectric layer between the reflective conductive pattern and the first electrode,
wherein the first electrode is in contact with a lateral surface of the reflective conductive pattern.

3. The display device of claim 1, wherein
the silicon nitride layer surrounds a lateral surface of the first electrode,
the first electrode is in contact with a lateral surface of the reflective conductive pattern, and
the pixel definition layer further comprises a lower silicon oxide layer between the silicon oxide layer and the semiconductor circuit substrate, the lower silicon oxide layer surrounds a lateral surface of the silicon nitride layer.

4. The display device of claim 1, wherein a thickness of the silicon nitride layer is in a range of about 50 Å to about 100 Å.

5. The display device of claim 1, wherein the tip structure has a bottom surface and an inclined surface,
wherein the inclined surface of the tip structure forms an acute angle relative to the bottom surface of the tip structure.

6. The display device of claim 5, wherein the acute angle is in a range of about 30° to about 60°.

7. The display device of claim 1, wherein each of the emission unit and the peripheral emission unit comprises:
a hole injection layer;
a hole transport layer on the hole injection layer;
an emission layer on the hole transport layer;
an electron transport layer on the emission layer; and
an electron injection layer on the electron transport layer,
wherein the hole injection layer of the emission unit and the hole injection layer of the peripheral emission unit are spaced apart from each other through the tip structure.

8. The display device of claim 7, wherein the second electrode further extends onto the peripheral emission unit.

9. The display device of claim 1, wherein the pixel definition layer further comprises:
a lower silicon nitride layer in contact with a lateral surface of the reflective conductive pattern; and
a lower silicon oxide layer between the silicon nitride layer and the semiconductor circuit substrate, the lower silicon oxide layer surrounds a lateral surface of the lower silicon nitride layer.

10. The display device of claim 9, wherein the reflective conductive pattern comprises:
a first reflective layer; and
a second reflective layer on the first reflective layer and in contact with the first electrode.

11. The display device of claim 10, wherein the first electrode comprises:
a 1-1^{st} electrode directly on the second reflective layer and comprising transparent conductive oxide; and
a 1-2^{nd} electrode on the 1-1^{st} electrode and comprising titanium nitride.

12. The display device of claim 11, wherein a thickness of the 1-2^{nd} electrode is in a range of about 10 Å to about 20 Å.

13. A display device, comprising:
a semiconductor circuit substrate comprising a pixel circuit;
a reflective conductive pattern on the semiconductor circuit substrate;
an emission element comprising a first electrode in contact with the reflective conductive pattern, an emission unit on the first electrode, and a second electrode on the emission unit, the emission element being on the semiconductor circuit substrate;
a pixel definition layer on the semiconductor circuit substrate and having an emission opening that exposes the first electrode; and
a peripheral emission unit on the pixel definition layer,
wherein the pixel definition layer comprises:
a 1-1^{st} silicon nitride layer directly on the first electrode;
a 1-2^{nd} silicon nitride layer on the 1-1^{st} silicon nitride layer; and
a silicon oxide layer directly on the 1-2^{nd} silicon nitride layer,
wherein the 1-2^{nd} silicon nitride layer comprises a protrusion that protrudes more inward from the emission opening than the 1-1^{st} silicon nitride layer,
wherein the silicon oxide layer defines a tip structure that protrudes more inward from the emission opening than the protrusion of the 1-1^{st} silicon nitride layer, and
wherein the peripheral emission unit is directly on the silicon oxide layer and electrically separated through the tip structure from the emission unit.

14. The display device of claim 13, wherein the pixel definition layer further comprises a lower silicon oxide layer between the 1-1^{st} silicon nitride layer and the 1-2^{nd} silicon nitride layer.

15. The display device of claim 13, wherein
the tip structure has a bottom surface and an inclined surface,
the inclined surface of the tip structure forms an acute angle relative to the bottom surface of the tip structure, and
an angle between an inner lateral surface of the protrusion of the 1-1^{st} silicon nitride layer and a top surface of the first electrode is greater than the acute angle.

16. The display device of claim 13, wherein
the protrusion of the 1-1^{st} silicon nitride layer provides a step difference, and
a portion of the silicon oxide layer is on the step difference.

17. The display device of claim 13, wherein each of the emission unit and the peripheral emission unit comprises:
a hole injection layer;
a hole transport layer on the hole injection layer;
an emission layer on the hole transport layer;
an electron transport layer on the emission layer; and
an electron injection layer on the electron transport layer,
wherein the hole injection layer of the emission unit and the hole injection layer of the peripheral emission unit are spaced apart from each other through the tip structure.

18. The display device of claim 13, further comprising an interlayer dielectric layer between the reflective conductive pattern and the first electrode,
wherein the first electrode is in contact with a lateral surface of the reflective conductive pattern.

19. An electronic device, comprising:
a display device;
a power module that supplies the display device with power; and
a processor connected to the display device,
wherein the display device comprises:
a semiconductor circuit substrate comprising a pixel circuit;
a reflective conductive pattern on the semiconductor circuit substrate;
an emission element comprising a first electrode in contact with the reflective conductive pattern, an emission unit on the first electrode, and a second electrode on the emission unit, the emission element being on the semiconductor circuit substrate;
a pixel definition layer on the semiconductor circuit substrate and having an emission opening that exposes the first electrode; and
a peripheral emission unit on the pixel definition layer,
wherein the pixel definition layer comprises:
a silicon nitride layer directly on the first electrode; and
a silicon oxide layer directly on the silicon nitride layer,
wherein the silicon oxide layer defines a tip structure that protrudes more inward from the emission opening than the silicon nitride layer, and
wherein the peripheral emission unit is directly on the silicon oxide layer and electrically separated through the tip structure from the emission unit.

20. The electronic device of claim 19, wherein a thickness of the silicon nitride layer is in a range of about 50 Å to about 100 Å.
